(19) United States
(12) Patent Application Publication
(10) Pub. No.: US 2008/0063982 A1
(43) Pub. Date: Mar. 13, 2008

(54) Fluids and methods of forming thereof

(76) Inventors: Stefan Wurm, Austin, TX (US); Siegfried Schwarzl, Neubiberg (DE)

Correspondence Address: SLATER & MATSIL LLP, 17950 PRESTON ROAD, SUITE 1000, DALLAS, TX, 75252, US

(21) Appl. No.: 11/502,281

(22) Filed: Aug. 10, 2006

(51) Int. Cl. G03F 7/00; G03B 27/32

(52) U.S. Cl. 430/311; 355/77

(57) ABSTRACT

Fluids for use in immersion lithography systems and methods of forming thereof are disclosed. In accordance with a preferred embodiment, a fluid for immersion lithography includes a liquid and a plurality of first atoms disposed in the liquid. The plurality of first atoms comprises at least one set of the plurality of first atoms arranged in a shape of a fullerene, the fullerene having an interior. At least one second atom is disposed in the interior of the at least one set of the plurality of first atoms arranged in the shape of the fullerene.

### TECHNICAL FIELD

The present invention relates generally to lithography systems for manufacturing semiconductor devices, and more particularly to fluids for use in immersion lithography systems and immersion exposure tools.

### BACKGROUND

Semiconductor devices are manufactured by depositing many different types of material layers over a semiconductor workpiece or wafer. The material layers are patterned using lithography. The material layers typically comprise thin films of conductive, semiconductive, and insulating materials that are patterned and etched to form integrated circuits (IC's).

For many years in the semiconductor industry, optical lithography techniques such as contact printing, proximity printing, and projection printing have been used to pattern material layers of integrated circuits. Projection printing is commonly used in the semiconductor industry using wavelengths of 248 nm or 193 nm, as examples. At such wavelengths, lens projection systems and transmission lithography masks are used for patterning, wherein light is passed through the lithography mask to impinge upon a wafer.

However, as the minimum feature sizes of IC's are decreased, the semiconductor industry is exploring the use of alternatives to traditional optical lithography techniques, in order to meet the demand for decreased feature sizes in the industry. For example, short wavelength lithography techniques such as Extreme Ultraviolet (EUV) Lithography, electron beam based lithography technologies, other non-optical lithographic techniques, and immersion lithography are under development as replacements for traditional optical lithography techniques.

In immersion lithography, the gap between the last lens element in the optics system and a semiconductor wafer is filled with a liquid, such as water, to enhance system performance. The presence of the liquid enables the index of refraction in the imaging plane, and therefore the numerical aperture of the projection system, to be greater than unity. Thus, immersion lithography has the potential to extend exposure tool minimum feature sizes down to about 45 nm or less, for example.

However, since immersion lithography is relatively new in the industry, there are several problems and issues that need to be resolved before the technology is ready to be implemented in full scale production. For example, one issue is finding optimal fluids to be dispersed between the lens system and the semiconductor device in immersion lithography systems.

Thus, what are needed in the art are improved fluids for use in immersion lithography systems.

### SUMMARY OF THE INVENTION

These and other problems are generally solved or circumvented, and technical advantages are generally achieved, by preferred embodiments of the present invention, which comprise novel fluids for use in immersion lithography systems.

In accordance with a preferred embodiment of the present invention, a fluid for immersion lithography includes a liquid and a plurality of first atoms disposed in the liquid. The plurality of first atoms comprises at least one set of the plurality of first atoms arranged in a shape of a fullerene, the fullerene having an interior. At least one second atom is disposed in the interior of the at least one set of the plurality of first atoms arranged in the shape of the fullerene.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a prior art graph showing some salts that have potential for use in fluids for immersion lithography systems;

FIG. 2 shows a cross-sectional view of a portion of an immersion exposure tool in accordance with a preferred embodiment of the present invention, wherein a fluid comprising fullerenes that include an index of refraction-altering material is disposed between a lens system and a semiconductor wafer during the lithography process;

FIG. 3 shows a perspective view of plurality of first atoms arranged in the shape of a fullerene in accordance with an embodiment of the present invention;

FIG. 4 shows a method of forming fullerenes in accordance with a preferred embodiment of the present invention;

FIG. 5 illustrates a method of embedding at least one second atom in a fullerene-shaped set of first atoms in accordance with an embodiment of the present invention;

FIG. 6 shows a set of first atoms arranged in a fullerene shape and enclosing a second atom in the interior thereof;

FIG. 7 shows a novel fluid in accordance with an embodiment of the present invention, wherein sets of first atoms having fullerene shapes that enclose a second atom are disposed in a surfactant leading to the attachment of surfactants to the fullerene bodies;

FIG. 8 illustrates a novel fluid in accordance with an embodiment of the present invention, wherein the second atom-containing fullerenes bound to the surfactant are disposed in a liquid; and

FIG. 9 shows an embodiment of the present invention, wherein a third atom may be disposed within the fullerenes, in addition to the second atom.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In immersion lithography, deep ultraviolet (DUV) light or energy, e.g., at about 193 nm, is used to expose a layer of photoresist, which is a polymer film that reacts when exposed to light or energy disposed on a workpiece. A fluid is disposed between a projection lens system and the workpiece. Immersion lithography is one of the main contenders for printing very small electronic circuit features on silicon wafers. Similar to a concept that has been used in optical microscopy, immersion fluids are beginning to be used in optical lithography between the last lens element of a lithographic imaging system and the resist layer in order to enabling imaging of smaller feature sizes onto the wafer.

Immersion lithography for imaging structures down to about 45 nm half pitch resolution currently uses clean water as an immersion fluid. The refractive index of water at a 193 nm wavelength used in immersion lithography is n_{fluid}=1.44. For achieving resolution in high numerical immersion lithography tools having features below 40 nm half pitch, higher refractive index fluids will be needed. Generally, immersion fluids are required to have a high refractive index, e.g., of about 1.2 to 1.8, and are required to be transparent in the deep ultraviolet (DUV) spectral range. Immersion fluids should also be photostable and chemically inert towards photoresists and optics of the projection lens system, and should be liquid to permit rapid scanning.

Various fluids are being researched for use in immersion lithography. It is particularly important to use a fluid in immersion lithography that will not damage the photoresist on a wafer and that will not damage the optics of the projection lens system of a lithography system, for example. The industry has tended to focus on water-based high index fluids having refractive indexes that are modified by introducing additional substances, although other options are also explored. For example, perfluoropolyether oils have been considered, but are not expected to yield high refractive indices.

Dielectric nanoparticles suspended in a liquid phase, or so-called nanocomposite fluids, have been considered, with a focus on the synthesis of alumina suspensions, as described by Chumanov, G., et al., in “Nanocomposite Liquids for 193 nm Immersion Lithography,” 2004, 14 pp., Sematech, Austin, Tex., which is hereby incorporated herein by reference. Alumina suspensions were synthesized through the hydrolysis and condensation of aluminium alkoxides in a two phase system. The size of the alumina particles ranged from 5 to 100 nm, and the refractive index of such suspension was expected to be around n=1.6. However, it is difficult to achieve a low variation in refractive index with very well controlled size distributions of nanoparticles, particularly, a very narrow size distribution around a small nanoparticle size, for example.

The addition of ionic surfactants has been considered, e.g., anionic and cationic surfactants that form aggregates (micelles) in aqueous solutions above a certain critical micelle concentration, as described by Zimmerman, P. A., et al., in “Amplification of the Index of Refraction of Aqueous Immersion Fluids by Ionic Surfactants,” Sematech Resist Advisory Group Meeting, 08-08-2004, 17 pp., Austin, Tex., which is hereby incorporated herein by reference. The introduction of zeolite nanoparticles to fluids has also been proposed, as described by Gejo, J. L., et al., in “Amplification of the Index of Refraction of Aqueous Immersion Fluids: Nanoparticle Dispersions,” Sematech Resist Advisory Group Meeting, September 2005, 21 pp., Sematech, Austin, Tex., which is hereby incorporated herein by reference. However, zeolite nanoparticles are problematic because of their wide particle size range (5 to 1,000 nm), which causes an excessive amount of Mie scattering.

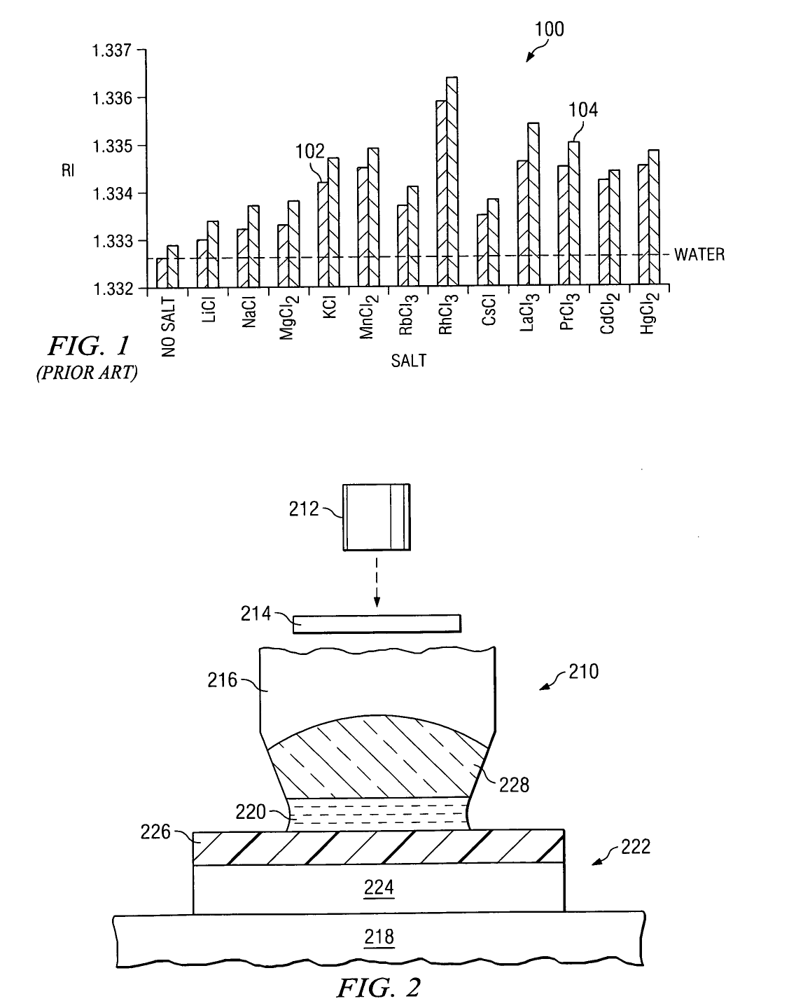

The addition of salts to fluids increases the refractive index but produces radicals under DUV irradiation that chemically attack optics and resist. Altering the refractive index of a fluid by adding a salt to the fluid is described by Gejo, J. L., et al., in “Amplification of the Index of Refraction of Aqueous Immersion Fluids: Nanoparticle Dispersions,” Sematech Resist Advisory Group Meeting, September 2005, 21 pp., Sematech, Austin, Tex., which is incorporated herein by reference. FIG. 1 is a graph 100 from p. 6 of Gejo et al., illustrating the refractive index (R1) for some salts, measured for convenience at a wavelength of 589 nm. The salts are shown in water with no sodium dodecyl sulfate (SDS) at 102, and the salts are shown in SDS at 104. The graph 100 illustrates that adding salts into solutions with surfactants yields an additional increase compared to the addition of salt only to pure water. This approach appears promising because the refractive index is increased; however, this approach has the disadvantage of producing radicals that corrode the optical elements or attack the resist. Adding salts to the immersion lithography fluid may result in corrosion of the layer of photoresist on the semiconductor wafer, and also may damage the optics of the lithography system, for example.

Willson, G., et al., in “University of Texas at Austin Immersion Lithography Progress Report,” Sematech Resist Advisory Group Meeting, 08-08-2004, 22 pp., Austin, Tex., which is hereby incorporated herein by reference, also disclose some salts considered as candidates for increasing the refractive index of water. Table 1 shows some combinations of salts disclosed on p. 10 by Willson et al., that could be used to increase the refractive index of water, with anion (the first row) and cation (the first column) combinations of salts illustrated.

TABLE 1

| | Cl | Br | Acetate | S₂O₃ | SCN | SO₄ | S₂O₄ | H₂PO₄ |
|---|---|---|---|---|---|---|---|---|
| Li | ✓ | ✓ | ✓ | | | | | |
| Na | ✓ | ✓ | ✓ | ✓ | ✓ | | | |
| K | ✓ | ✓ | ✓ | ✓ | | | | |
| Rb | ✓ | ✓ | ✓ | | | | | |
| Cs | ✓ | ✓ | ✓ | | | | | |
| NH₄ | ✓ | ✓ | ✓ | ✓ | ✓ | ✓ | ✓ | ✓ |
| TMA | ✓ | ✓ | ✓ | | | | | ✓ |

However, most of these salts, indicated by the checkmarks, chemically formed in aqueous solutions, comprise very aggressive fluids.

Thus, although the introduction of salts appears to have the most promise in increasing the index of refraction of a liquid, an adequate method of introducing salts to a liquid for immersion lithography that does not impact the optics lifetime or degrade or attack the resist on a semiconductor wafer has yet to be found.

Embodiments of the present invention provide novel methods of adding salts and other substances to a fluid to alter the properties of the fluid, such as the refractive index or index of refraction. Fullerene cages are used to contain the property-altering substance, preventing the salt or other substance from causing damage to materials the fluid comes into contact with.

A fullerene is a chemical having a dome or cage-like structure of atoms. Fullerenes are typically substantially spherical, for example. Carbon may be formed in the shape of a fullerene, e.g., C₆₀. Fullerenes comprise a plurality of atoms, usually of the same type, bonded together in a structure of a cage and having a hollow interior. The cage structures typically comprise many faces shaped as hexagons and pentagons, similar to the shape of geodesic domes, for example. Materials other than carbon may also be formed into fullerenes and may have different numbers of atoms in each fullerene, for example.

Embodiments of the present invention achieve technical advantages by using fullerenes to contain atoms or molecules within the cage-like structure of a fullerene, changing the properties of a fluid, yet the cage-like structure of the fullerenes prevents the atoms or molecules from deleteriously affecting objects or substances the fluid comes into contact with.

FIG. 2 illustrates an immersion lithography system 210 or immersion tool 210 in accordance with an embodiment of the present invention, wherein a fluid 220 comprising fullerenes is disposed between a last lens 228 of a projection lens system 216 and a semiconductor device 222. A cross-sectional view of a portion of an immersion exposure tool 210 in accordance with a preferred embodiment of the present invention is shown, wherein a fluid 220 comprising fullerenes that includes an index of refraction-altering material is disposed between and adjacent a lens system 216 and a semiconductor wafer 222 during the lithography process.

A support 218 for the device 222 is adapted to support the device 222 during the lithography process. The wafer support 218 may comprise a wafer stage or exposure chuck, for example. A lithography mask 214 is disposed between an illuminator 212 and the projection lens system 216. The illuminator 212 is adapted to expose the semiconductor device 222 to light or energy through the mask 214 and projection lens system 216 to transfer the pattern of the mask 214 to the layer of photoresist 226 disposed over the workpiece 224 of the semiconductor device 222. The semiconductor device 222 and the mask 214 may both be moved from one side to the other during a scanning process to expose the layer of photoresist 226, for example.

The fluid 220 preferably comprises a liquid such as de-ionized water. The fluid 220 may also comprise other liquids, such as water, highly purified water, distilled water, or distilled de-ionized water. The fluid 220 preferably includes a plurality of first atoms, wherein sets of the first atoms comprise the shape of at least one fullerene. At least one second atom is disposed in an interior of at least some of the fullerenes of first atoms. The fluid 220 may also include a surfactant, to be described further herein. In some embodiments, the fluid 220 may include a solvent, also to be described further herein.

The fluid 220 is introduced between the last element or lens 228 of the projection lens system 216 and the semiconductor device 222 during the exposure process, e.g., by an immersion head (not shown) clamped to the end of the lens system 216 or to another part of the immersion exposure tool 210. The immersion head is also referred to in the art as a shower head, for example.

The wafer support 218 and the wafer 222 are moved during the patterning of the individual die or regions of die on the wafer 222, e.g., from one side to another, and thus the immersion exposure tool 210 is also referred to in the art as an immersion lithography scanner. The projection lens system 216 is typically quite large and therefore usually remains stationary, for example. The wafer support 218 typically has recessed areas formed therein so that the wafer 222 is recessed when placed on the wafer support 218, for example, not shown.

The fluid 220 is typically provided by a nozzle or by input and output ports within the immersion head (not shown), for example. During an exposure process, the fluid 220 generally continuously flows, to provide temperature stability for the immersion head and other components of the immersion exposure tool 210. In some immersion exposure tools 210, when the lens system 216 is not being used to expose the wafer 222, a closing disk may be used to close the end of the immersion head. The immersion exposure tool 210 may include a fluid handler adapted to provide the fluid 220 which may be coupled to the immersion head by a hose or other fluid-delivering means, for example.

The wafer 222 typically includes a workpiece with a layer of radiation sensitive material 226 such as a photoresist disposed thereon. The pattern from the mask or reticle 214 is imaged onto the photoresist 226 using a beam of radiation or light (e.g., energy) emitted from the lens system 216. The beam is emitted from an energy source 212, such as a light source or an illuminator, and the beam is passed through the lens system 216 to the photoresist 226 of the wafer 222. After exposure of the photoresist, the patterned photoresist is later used as a mask while portions of a material layer of the semiconductor workpiece 224 disposed over the workpiece 224 or potions of the workpiece 224 are etched away or are otherwise altered.

The fluid 220 makes contact with a portion of the top surface of the wafer 222 and the bottom surface of the last element 228 of the projection lens system 216. The immersion head (not shown) includes ports that may comprise an annular ring of ports for supplying the fluid 220 between the wafer 222 and the immersion head. The ports may comprise input and output ports for injecting and removing the fluid 220, for example. In some embodiments, a fluid pad between the projection lens system 216 and the wafer 222 is moved from field to field as the wafer 222 is moved, i.e., the entire wafer 222 is not covered with water: only the portion under the last lens element 228 of the projection lens system 216 is covered in the fluid 222 during an exposure process.

In accordance with a preferred embodiment of the present invention, a novel fluid 220 for use in immersion lithography systems and other applications is disclosed herein. Embodiments of the present invention also include methods of creating the fluid 220, and immersion lithography systems 210 and tools that utilize the fluid 220. Embodiments of the present invention also include methods of fabricating semiconductor devices 222 using an immersion lithography system 210 implementing the fluid 220.

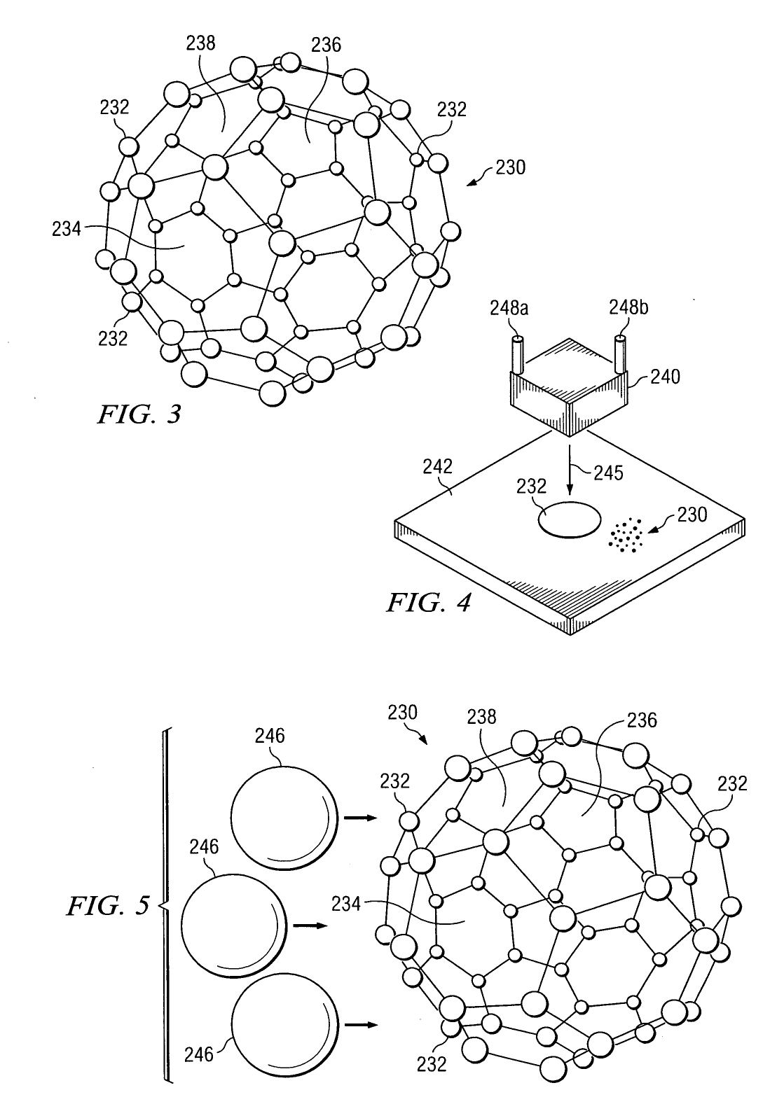

FIG. 3 shows a perspective view of a plurality of first atoms 232 arranged in the shape of a fullerene 230 in accordance with an embodiment of the present invention. The plurality of first atoms 232 preferably comprise atoms of at least one type, and may comprise two or more atoms of different types, in some embodiments. The first atoms 232 preferably comprise carbon (C) in some embodiments, although other materials may also be used for the first atoms 232. The first atoms 232 may comprise carbon-nitrogen and boron-nitride fullerenes and also fullerenes derived from hexagonal (i.e., 2H-type) layered chalcogenide or halide structures having a general stoichiometry MX2, as examples, wherein M comprises a metal and X2 comprises a chalcogenide or halide, for example. A set of a plurality of the first atoms 232 is arranged in the shape of a fullerene 230, as shown. The first atoms 232 may be shaped in fullerenes 230 by exposing the first atoms 232 to energy, e.g., to a laser beam, electron beam, photon beam, or other types of energy.

The fullerene 230 comprises a plurality of hexagon faces 234 and pentagon faces 236, for example. Some of the first atoms 232 comprise hexagon faces 234 and others comprise pentagon faces 236, as shown, for example. In the example shown, a C₆₀ is shown, that includes 20 hexagon faces 234 and 12 pentagon faces 236, with each pentagon face 236 being surrounded by hexagon faces 236, for example. The C₆₀ fullerene 230 may be about 7 Angstroms in diameter, for example. Alternatively, the fullerene 230 may comprise other materials and may comprise other sizes, for example.

FIG. 4 shows a method of forming fullerenes 230 in accordance with a preferred embodiment of the present invention. A plurality of the first atoms 232 is provided and may be placed on a support 242. For example, raw carbon 232, e.g., carbon dust, may be provided. An energy source 240 is used to bombard the plurality of first atoms 232 with energy 245 and form the fullerenes 230. The energy source 240 may comprise two electrodes 248a and 248b, and a voltage may be applied across the electrodes 248a and 248b to cause the energy 245 to be emitted from the energy source 240, for example, as shown.

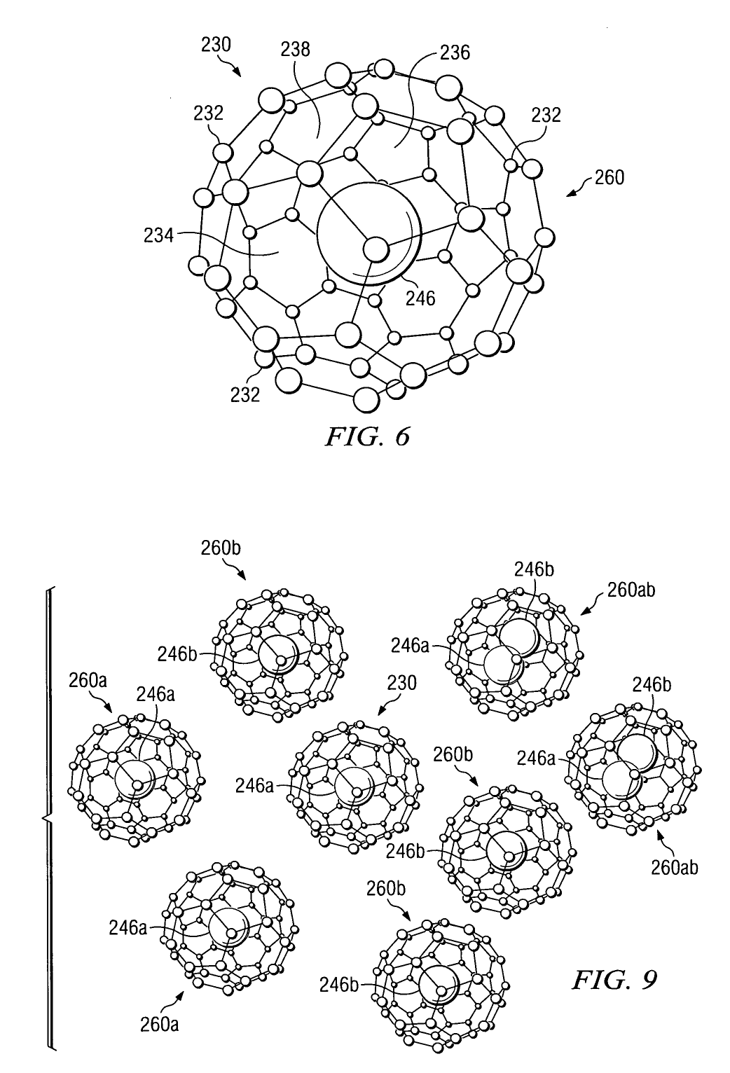

FIG. 5 illustrates a method of embedding at least one second atom 246 in a fullerene-shaped set 230 of first atoms 232 in accordance with an embodiment of the present invention. A C₆₀ molecule is preferably doped with an atom 246 or small molecule current (which may comprise neutral or ion currents, as examples). The at least one second atom 246 may be disposed in the interior 238 of at least one of the plurality of fullerenes 230 by bombarding the plurality of fullerenes 230 with a plurality of the second atoms 246 using a high current ion beam, or by implanting the at least one second atom 246 into the plurality of fullerenes 230, for example. FIG. 6 shows a set of first atoms 260 shaped in a fullerene shape 230 and enclosing a second atom 246 in the interior 238 thereof.

The second atom 246 preferably comprises a different type of atom than the first atoms 232, for example. The second atom 246 preferably comprises a salt, an oxide, an insulator, a conductor, a semiconductor, a metal, an acid, a polymer, a chloride, a fluoride, or combinations thereof, as examples, although other materials may also be used. The second atom 246 may comprise one or more atoms, and may comprise one or more molecules, for example. The second atoms 246 preferably comprise LiCl, LiBr, Li-Acetate, CdCl₂, KCl, KBr, K-Acetate, KS₂O₃, HgCl₂, LaCl₃, NaCl, NaBr, Na-Acetate, NaS₂O₃, NaSCN, MgCl₂, MnCl₂, SiCl₄, TiNO₃, RbNO₃, RbBr, Rb-Acetate, SmCl₃, KI, TbCl₃, LuCl₃, PbCl₂, TlF, Ba(SCN)₂, NbCl₅, CeCl₃, NdCl₃, EuCl₃, Gd(NO₃)₃, HOCl₃, TaCl₅, GdCl₃, TlI, RbCl₃, RhCl₃, CsCl, CsBr, Cs-Acetate, NH₄C₁, NH₄Br, NH₄-Acetate, NH₄—S₂O₃, NH₄—SCN, NH₄—SO₄, NH₄—S₂O₄, NH₄—H₂PO₄, TMA-Cl, TMA-BR, TMA-Acetate, PrCl₃, Al₂O₃, HFO₂, Sio₂, BaF₂, CaF₂, LaF₂, AlPO, S, O C, F₃, H, Na, Al, Si, Ca, Sr, Si₃N₄, SiC, or combinations thereof, as examples, although other materials may also be used.

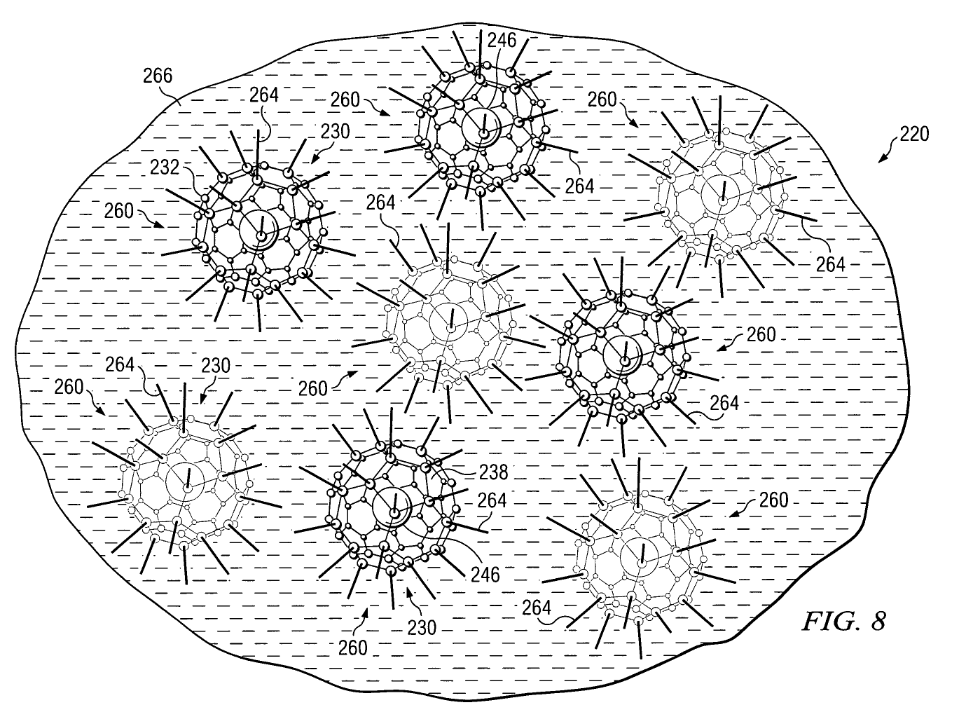

Preferably, the second atoms 246 are adapted to alter a property of the fluid being manufactured, e.g., fluid 220 shown in FIGS. 2 and 8. In some embodiments, for example, the second atom 246 affects an index of refraction of the fluid 220, and in some embodiments, the second atom 246 increases the index of refraction of the fluid 220, for example. The second atom 246 may also be adapted to alter other properties of the fluid 220, for example.

The second atom 246 may be formed in the interior 238 of the fullerenes 230 by introducing gases of the second atom 246 to the fullerenes 230 of the first atoms 232, for example. The fullerenes 230 may be formed in the presence of the gas of the second atom 246, forming the second atoms 246 in the fullerenes 230, for example.

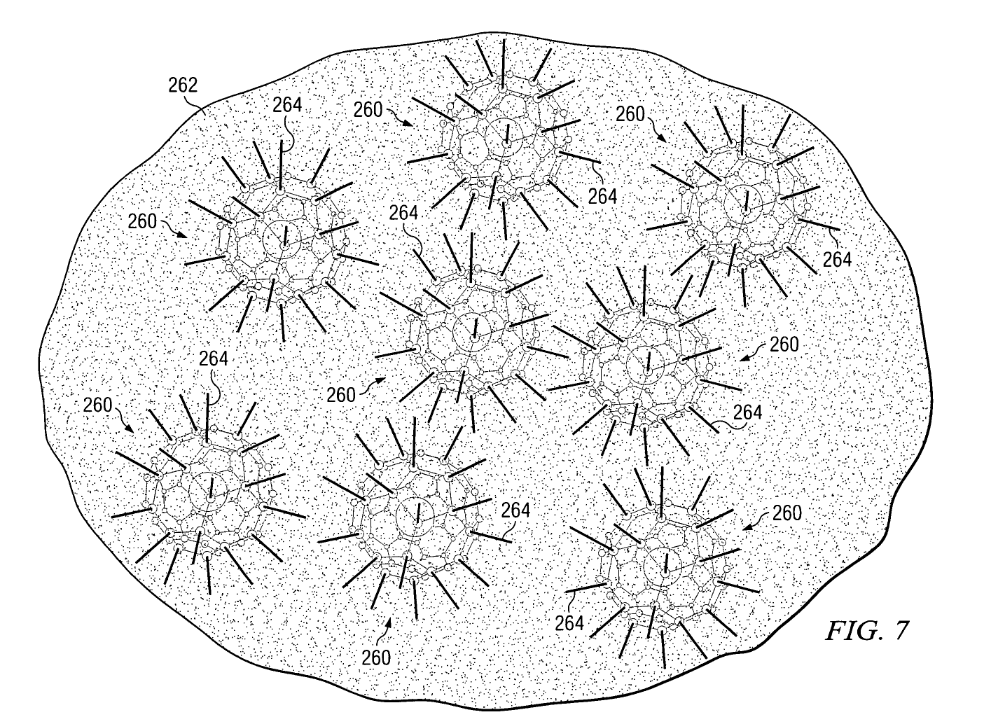

In some embodiments of the present invention, before the fullerenes 260 containing the second atom 246 in the interior 238 thereof are disposed in a liquid, preferably, the fullerenes 260 are combined with a surfactant 262. The surfactant 262 prevents the fullerene 260 cages from grouping together, for example. FIG. 7 shows a novel fluid in accordance with an embodiment of the present invention, wherein sets of first atoms 232 having fullerene shapes 230 that each enclose a second atom 246 are disposed in a surfactant 262. A portion 264 of the surfactant 262 bonds with the first atoms 232 of the fullerenes 230, as shown. The surfactant 264 bonded with the first atoms 232 of the fullerenes 230 is advantageous in making the fullerenes 260 bond easier to a liquid 266 that is added later, as shown in FIG. 8, for example.

The surfactant 262 preferably comprises an anion or a cation. For example, the surfactant 262 may comprise an anionic surfactant, such as sodium dodecyl sulfate, sodium decyl sulfate, or sodium tetradecyl sulfate. The surfactant 262 may comprise a cationic surfactant, such as cetyl trimethyl ammonium chloride or cetyl trimethyl ammonium bromide. The surfactant 262 may alternatively comprise other materials, for example.

FIG. 8 illustrates a novel fluid 220 in accordance with an embodiment of the present invention, wherein the second atom-containing fullerenes 230 bound to the surfactant 264 shown in FIG. 7 are disposed in a liquid 266. The fluid 220 comprises a fluid for immersion lithography, and includes a liquid 266. The liquid 266 preferably comprises water, highly purified water, distilled water, de-ionized water, or distilled de-ionized water, as examples, although other liquids may also be used. A plurality of first atoms 232 are disposed in the liquid 266, the plurality of first atoms 232 comprising at least one set of the plurality of first atoms 232 arranged in a shape of a fullerene 230. Preferably, a plurality of fullerenes 230 is disposed in the liquid 266, as shown. The fullerenes 230 have an interior 238 and at least some of the fullerenes 230 include at least one second atom 246 disposed in the interior 238 thereof, as shown. Optionally, a surfactant 264 may be bonded to at least one of the at least one set of the plurality of first atoms 232 of the fullerenes 230, as shown.

In some embodiments, the liquid 266 may comprise a solvent, for example. The solvent preferably comprises a solvent in the aromatic family, in one embodiment. The solvent may comprise toluene, xylene, hexane, tetahydrofuran (THF), acetonitrile (ACN), or octanol, as examples. The liquid may also include a cosolvent-water systems where appropriate for the type of solvent, or mixtures of a solvent and water, such as methanol-water, ethanol-water, tetrahydrofuran-water, acetonitrile-water, or octanol-water, as examples. The liquid may alternatively comprise other solvents.

Advantageously, the at least one second atom 246 alters a property of the liquid 220, such as by increasing the index of refraction of the liquid 220, and the fullerene cage 230 comprising the first atoms 232 prevents the at least one second atom 246 from deleteriously affecting a material exposed to the fluid 220, e.g., under intensive DUV light exposure, such as the layer of photoresist 226 formed on the workpiece 224 and/or the projection lens system 216 optics (see FIG. 2). Preferably, the fluid 220 comprises an index of refraction of about 1.2 to about 1.8, in accordance with embodiments of the present invention, for example.

In some embodiments, for example, the second atoms 246 are adapted to provide matching of the index of refraction n_{fluid} of the fluid 220 with the index of refraction of the projection lens system 216, e.g., the index of refraction n_{glass} of the last element 228 of the projection lens system 216, and also with the index of refraction nᵣₑₛᵢₛₜ of the layer of photoresist 226, as shown in FIG. 2.

FIG. 9 shows an embodiment of the present invention, wherein a third atom 246b may be disposed within the fullerenes 230 comprising the first atoms 232, in addition to the second atom 246a. Some second atoms 246a may be formed in some of the fullerenes 230, as shown at 260a. Some third atoms 246b may be formed in other of the fullerenes 230, as shown at 260b. Some second atoms 246a and third atoms 246b may be formed in others of the fullerenes, as shown at 260ab, for example. Four or more different types of atoms may be inserted into the interiors 238 of the fullerenes 230 in accordance with embodiments of the present invention, for example.

Embodiments of the present invention include semiconductor devices 222 manufactured using the novel fluids 220 described herein in an immersion lithography system 210, and methods of fabricating semiconductor devices 222. For example, referring again to FIG. 2, the workpiece 224 may include a semiconductor substrate comprising silicon or other semiconductor materials, for example. The workpiece 224 may also include active components or circuits formed thereon, not shown. The workpiece 224 may comprise silicon oxide over single-crystal silicon, for example. The workpiece 224 may comprise a silicon-on-insulator (SOI) substrate, as another example. The workpiece 224 may include conductive layers or other semiconductor elements, e.g. transistors, diodes, etc. Compound semiconductors, GaAs, InP, Si/Ge, or SiC, as examples, may be used in place of silicon. The workpiece 224 preferably comprises a material layer or layers to be patterned formed thereon, and a radiation or energy sensitive material such as a photoresist 226 disposed over the material layer or layers to be patterned, not shown.

To pattern a material layer of the workpiece 224 or the workpiece 224, energy such as light is directed from the last lens element 228 through the fluid 220 and towards the layer of radiation sensitive material 226 disposed on the workpiece 224, e.g., in the region of the workpiece 224 disposed immediately beneath the last lens element 228. The energy has preferably been passed through the lithography mask 214 comprising the desired pattern for the material layer or layers to be patterned on the workpiece 224, for example. The layer of radiation sensitive material 226 is then developed, and the layer of radiation sensitive material 226 is used as a mask while the material layer or layers of the workpiece 224 to be patterned are etched away, for example.

Preferably, a workpiece 222 is affected with the projection lens system 210 with the novel fluid 220 disposed between the projection lens system 216 and the layer of photoresist 226 of the semiconductor device 222. For example, affecting the workpiece using the lithography mask comprises patterning the layer of photosensitive material 226 using the lithography mask 214 and the projection lens system 216. Affecting the workpiece 224 may comprise altering the material layer of the workpiece 224 through the patterned layer of photosensitive material 226. For example, altering the material layer of the workpiece 224 may comprise etching the material layer, implanting the material layer with a substance, or depositing another material layer over the material layer.

In one embodiment, a method of lithography for semiconductor devices 222 includes providing an immersion exposure tool 210 having a wafer support 218, a projection lens system 216, an immersion head (e.g., proximate the last element 228 of the lens system 216, not shown) adapted to dispose a fluid 220 between the projection lens system 216 and the wafer support 218, and an energy source 212 proximate the projection lens system 216. A workpiece 224 is provided having a radiation sensitive material 226 disposed thereon. The workpiece 224 is positioned on the wafer support 218, and a novel fluid 220 described herein is disposed between the workpiece 224 and the projection lens system 216. The fluid 220 includes a liquid 266 (see FIG. 8) and a plurality of fullerene-shaped first atoms 232 disposed in the liquid 266, at least one second atom 246 being disposed in the interior 238 of some of the plurality of fullerene-shaped first atoms 232. The radiation sensitive material 226 of the workpiece 224 is exposed to radiation from the energy source 212. The radiation sensitive material 226 is then used to pattern a material layer or layers of the workpiece 224. The material layers may comprise a conductive material, a semiconductive material, or an insulating material, as examples.

Advantages of preferred embodiments of the present invention include providing novel fluids 220 for immersion lithography systems 210 and other applications. The fluids 220 prevent damage to a semiconductor workpiece 222, to portions of the immersion lithography system, and other materials that come into contact with the fluid 220, yet allow for the refractive index of the fluid or other properties of the fluid 220 to be adjusted or tuned.

The novel fluids 220 and methods of forming thereof are useful in other applications where certain properties of a fluid 220 are required, yet changing the fluid 220 by adding a substance cannot be achieved because the fluid 220 would be created that would be damaging or that would cause an undesired effect. Fullerenes 230 may be implanted or embedded with the property-altering substance 246a and/or 246b, and the fullerene structures 230 prevent the property-altering substance, e.g., the second atoms 246a and/or third atoms 246b, from deleteriously affecting materials that the fluid 220 comes into contact with.

Advantageously, the fullerenes 230 may comprise C₆₀, which are sufficiently small so that Mie scattering does not present a problem. One second atom 246a or third atom 246b may be disposed inside the fullerenes 230, or alternatively, larger fullerenes 230 may be used so that two or more atoms 246a and/or 246b, or alternatively, small molecules, may be disposed inside the fullerenes, 230, for example.

Furthermore, advantageously, the chemistry of the second atom 246 is separated using physics, by caging the second atom 246 within the fullerenes 230. Therefore, a desired physical property of the fluid 220 is achieved while avoiding deleterious chemical effects from the presence of the second atom 246.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A fluid for immersion lithography, the fluid comprising:
a liquid;
a plurality of first atoms disposed in the liquid, the plurality of first atoms comprising at least one set of the plurality of first atoms arranged in a shape of a fullerene, the fullerene having an interior; and
at least one second atom disposed in the interior of the at least one set of the plurality of first atoms arranged in the shape of the fullerene.

2. The fluid according to claim 1, further comprising a surfactant bonded to at least one of the at least one set of the plurality of first atoms.

3. The fluid according to claim 1, wherein the plurality of first atoms comprises carbon (C), carbon-nitrogen, boron-nitride, or a metal chalcogenide or halide.

4. The fluid according to claim 1, wherein the at least one second atom comprises a salt, an oxide, an insulator, a conductor, a semiconductor, a metal, an acid, a polymer, a chloride, a fluoride, or combinations thereof.

5. The fluid according to claim 1, wherein the at least one second atom affects an index of refraction of the fluid.

6. An immersion lithography system including the fluid according to claim 1.

7. A method of forming a fluid, the method comprising:
providing a plurality of fullerenes, each fullerene comprising a cage comprised of a plurality of first atoms, each fullerene comprising an interior;
disposing at least one second atom in the interior of at least one of the plurality of fullerenes; and
disposing the at least one of the plurality of fullerenes having the at least one second atom in the interior thereof in a liquid, wherein the at least one second atom alters a property of the liquid and the fullerene cage prevents the at least one second atom from deleteriously affecting a material exposed to the fluid.

8. The method according to claim 7, wherein disposing the at least one second atom in the interior of at least one of the plurality of fullerenes comprises bombarding the plurality of fullerenes with a plurality of the second atoms or implanting the at least one second atom into the plurality of fullerenes.

9. The method according to claim 7, further comprising adding a surfactant to the plurality of fullerenes, after disposing the at least one second atom in the interior of at least one of the plurality of fullerenes.

10. The method according to claim 7, wherein disposing the at least one second atom comprises disposing an atom different than the plurality of first atoms, further comprising disposing at least one third atom in at least one of the plurality of fullerenes, the third atom being different than the at least one second atom or the plurality of first atoms.

11. The method according to claim 10, wherein disposing the at least one third atom comprises disposing the at least one third atom in a fullerene wherein the at least one second atom resides, or wherein disposing the at least one third atom comprises disposing the at least one third atom in a fullerene wherein the at least one second atom does not reside.

12. The method according to claim 7, wherein providing the plurality of fullerenes comprises providing a plurality of carbon atoms and bombarding the carbon atoms with energy to form the plurality of fullerenes.

13. The method according to claim 7, wherein disposing at least one second atom in the interior of at least one of the plurality of fullerenes comprises disposing at least one second atom comprising LiCl, LiBr, Li-Acetate, CdCl₂, KCl, KBr, K-Acetate, KS₂O₃, HgCl₂, LaCl₃, NaCl, NaBr, Na-Acetate, NaS₂O₃, NaSCN, MgCl₂, MnCl₂, SiCl₄, TiNO₃, RbNO₃, RbBr, Rb-Acetate, SmCl₃, KI, TbCl₃, LuCl₃, PbCl₂, TlF, Ba(SCN)₂, NbCl₅, CeCl₃, NdCl₃, EuCl₃, Gd(NO₃)₃, HOCl₃, TaCl₅, GdCl₃, TlI, RbCl₃, RhCl₃, CsCl, CsBr, Cs-Acetate, NH₄C₁, NH₄Br, NH₄-Acetate, NH₄—S₂O₃, NH₄—SCN, NH₄—SO₄, NH₄—S₂O₄, NH₄—H₂PO₄, TMA-Cl, TMA-BR, TMA-Acetate, PrCl₃, Al₂O₃, HFO₂, Sio₂, BaF₂, CaF₂, LaF₂, AlPO, S, O, C, F₃, H, Na, Al, Si, Ca, Sr, Si₃N₄, SiC, or combinations thereof.

14. A method of manufacturing a semiconductor device, the method comprising:
providing a workpiece;
disposing a projection lens system proximate the workpiece;
disposing a fluid between the workpiece and the projection lens system, the fluid comprising a plurality of first atoms, at least some of the plurality of first atoms being arranged in the shape of a fullerene, at least one second atom being disposed within the fullerene-shaped plurality of first atoms; and
affecting the workpiece with the projection lens system.

15. The method according to claim 14, further comprising disposing an energy source proximate the projection lens system and disposing a lithography mask between the energy source and the projection lens system, wherein providing the workpiece comprises providing a workpiece having a layer of photosensitive material disposed thereon, and wherein affecting the workpiece comprises patterning the layer of photosensitive material by directing energy from the energy source through the lithography mask and projection lens systems towards the workpiece.

16. The method according to claim 14, wherein providing the workpiece comprises providing a workpiece having a material layer disposed thereon, the layer of photosensitive material being disposed over the material layer, further comprising exposing the layer of photosensitive material, and wherein affecting the workpiece comprises altering the material layer through the patterned layer of photosensitive material.

17. The method according to claim 16, wherein altering the material layer comprises etching the material layer, implanting the material layer with a substance, or depositing another material layer over the material layer.

18. The method according to claim 16, wherein the material layer comprises a conductive material, a semiconductive material, or an insulating material.

19. A semiconductor device manufactured in accordance with the method of claim 18.

20. A method of lithography for semiconductor devices, the method comprising:
providing an immersion exposure tool having a wafer support, a projection lens system, an immersion head adapted to dispose a fluid between the projection lens system and the wafer support, and an energy source proximate the projection lens system;
providing a workpiece having a radiation sensitive material disposed thereon;
positioning the workpiece on the wafer support;
disposing the fluid between the workpiece and the projection lens system, the fluid including a liquid and a plurality of fullerene-shaped first atoms disposed in the liquid, at least one second atom being disposed in the interior of some of the plurality of fullerene-shaped first atoms; and
exposing the radiation sensitive material of the workpiece to radiation from the energy source.

21. The method according to claim 20, wherein disposing the fluid comprises disposing a fluid wherein the at least one second atom is different than the plurality of first atoms.

22. The method according to claim 20, wherein disposing the fluid comprises disposing a fluid wherein the at least one second atom comprises a material that increases an index of refraction of the fluid.

23. The method according to claim 20, wherein disposing the fluid comprises disposing a fluid wherein the at least one second atom comprises a material that is capable of deleteriously affecting the radiation sensitive material of the workpiece or the projection lens system, and wherein the plurality of fullerene-shaped first atoms prevents the at least one second atom from deleteriously affecting the radiation sensitive material of the workpiece or the projection lens system.

24. The method according to claim 20, wherein disposing the fluid comprises disposing a fluid including a liquid comprising water, purified water, distilled water, de-ionized water, distilled de-ionized water, a solvent, and/or a surfactant.

25. The method according to claim 24, wherein disposing the fluid comprises disposing a fluid including a surfactant comprising sodium dodecyl sulfate, sodium decyl sulfate, sodium tetradecyl sulfate, cetyl trimethyl ammonium chloride, or cetyl trimethyl ammonium bromide.

26. The method according to claim 24, wherein disposing the fluid comprises disposing a solvent comprising toluene, xylene, hexane, tetahydrofuran (THF), acetonitrile (ACN), or octanol, a mixture of a solvent and water, methanol-water, ethanol-water, tetrahydrofuran-water, acetonitrile-water, and/or octanol-water.

27. The method according to claim 20, wherein disposing the fluid comprises disposing a fluid comprising an index of refraction of about 1.2 to 1.8.
